(19) United States
(12) Patent Application Publication
(10) Pub. No.: US 2026/0164643 A1
(43) Pub. Date: Jun. 11, 2026

(54) SEMICONDUCTOR DEVICE, MANUFACTURING METHOD THEREOF AND MEMORY DEVICE

(71) Applicant: Yangtze Memory Technologies Co., Ltd., Wuhan (CN)

(72) Inventors: Yaqin LIU, Wuhan (CN); Zongliang HUO, Wuhan (CN); Liang CHEN, Wuhan (CN); Wei LIU, Wuhan (CN)

(21) Appl. No.: 19/224,406

(22) Filed: May 30, 2025

(30) Foreign Application Priority Data
Dec. 10, 2024 (CN) 202411817868.0

(51) Int. Cl. H10B 12/00; H01L 23/00; H01L 25/065; H01L 25/18; H10B 80/00

(52) U.S. Cl. CPC H10B 12/33; H10B 12/05; H10B 80/00; H10W 90/00; H10W 90/792

(57) ABSTRACT

Examples of the present disclosure disclose a semiconductor device, a manufacturing method thereof and a memory device. The semiconductor device includes a plurality of bit lines and a conductive structure. The plurality of bit lines are located on a first side of a transistor and are arranged along a first direction. The conductive structure is located on a second side of the transistor and includes a first conductive portion and a second conductive portion. The first conductive portion is located between adjacent bit lines, and the second conductive portion is located on a side of the plurality of bit lines away from the transistor. The second conductive portion extends along the first direction and is connected to the first conductive portion between the adjacent bit lines.

### CROSS-REFERENCE TO RELATED APPLICATIONS

This application claims the benefit of priority to Chinese Patent Application No. 202411817868.0, filed on Dec. 10, 2024, the disclosure of which is hereby incorporated by reference in its entirety.

### TECHNICAL FIELD

Examples of the present disclosure relate to the field of semiconductor technology, and relate to, but are not limited to, a semiconductor device, a manufacturing method thereof, and a memory device.

### BACKGROUND

A semiconductor memory is classified into a volatile memory and a non-volatile memory according to whether the stored data is retained when the semiconductor memory is powered off, wherein the volatile memory whose data is lost during power off may comprise a Static Random-Access Memory (SRAM) and a Dynamic Random Access Memory (DRAM), and the DRAM has attracted extensive attention due to its higher density and lower cost.

With the iteration of DRAM products, the size of DRAM shrinks continuously, and the storage density per unit area is greatly improved. However, an increase in storage density results in that the performance of the device is affected.

### SUMMARY

The present disclosure provides a semiconductor device, a manufacturing method thereof and a memory device.

According to a first aspect of examples of the present disclosure, a semiconductor device is provided, which comprises a plurality of bit lines and a conductive structure, the plurality of bit lines are located on a side of a transistor and are arranged along a first direction, the conductive structure is located on a side of the transistor and comprises a first conductive portion and a second conductive portion, the first conductive portion is located between adjacent bit lines of the plurality of bit lines, and the second conductive portion is located on a side of the plurality of bit lines away from the transistor, wherein the second conductive portion extends along the first direction and is connected to the first conductive portion between the adjacent bit lines.

In some examples, the conductive structure comprises a plurality of conductive structures arranged along a second direction intersecting with the first direction.

In some examples, the first conductive portions of the plurality of conductive structures extend along the second direction and are connected to each other.

In some examples, the semiconductor device further comprises a first contact structure and a second contact structure, the first contact structure is located on a side of the bit line away from the transistor and is connected to the bit line, wherein the first contact structure is located between adjacent conductive structures of the plurality of conductive structures, the second contact structure is located on a side of the conductive structure away from the bit line and is connected to the conductive structure, wherein the second contact structure and the first contact structure are spaced apart.

In some examples, the second contact structure comprises a plurality of second contact structures, the plurality of second contact structures are respectively connected to the plurality of conductive structures, wherein the plurality of second contact structures are connected to each other.

In some examples, a size of the conductive structure in the second direction is greater than a distance between the adjacent conductive structures.

In some examples, a ratio of the size of the conductive structure in the second direction to the distance between the adjacent conductive structures is greater than 5:1.

In some examples, a height of the first conductive portion is greater than a height of the bit line.

In some examples, the semiconductor device further comprises a first contact structure located on a side of the bit line away from the transistor and connected to an end of the bit line.

In some examples, a distance between the second conductive portion and the bit line is greater than 0.

In some examples, the distance between the second conductive portion and the bit line is greater than a pitch between the adjacent bit lines.

In some examples, a gap exists between the conductive structure and the bit line.

In some examples, the gap is an air gap.

In some examples, the conductive structure is configured to be connected to a fixed potential.

According to a second aspect of examples of the present disclosure, a memory device is provided, which comprises a first semiconductor structure and a second semiconductor structure, the first semiconductor structure comprises a memory cell array, a plurality of bit lines and a conductive structure, the plurality of bit lines are located on a side of the memory cell array and are arranged along a first direction, the conductive structure extends along the first direction and covers at least portion of the bit line, the second semiconductor structure comprises a peripheral circuit connected to the memory cell array through the plurality of bit lines.

In some examples, the conductive structure comprises a plurality of conductive structures, the plurality of conductive structures are arranged along a second direction intersecting with the first direction.

In some examples, the conductive structure has a first conductive portion protruding toward the bit line, and the first conductive portion extends until it is between adjacent bit lines of the plurality of bit lines.

In some examples, the first conductive portions of the plurality of conductive structures extend along the second direction and are connected to each other.

In some examples, a height of the first conductive portion is greater than a height of the bit line.

In some examples, the first semiconductor structure further comprises a first contact structure and a second contact structure, the first contact structure is located on a side of the bit line away from the memory cell array and is connected to the bit line, wherein the first contact structure is located between adjacent conductive structures of the plurality of conductive structures, the second contact structure is located on a side of the conductive structure away from the bit line and is connected to the conductive structure, wherein the second contact structure and the first contact structure are spaced apart.

In some examples, the second contact structure comprises a plurality of second contact structures, the plurality of second contact structures are respectively connected to the plurality of conductive structures, wherein the plurality of second contact structures are connected to each other.

In some examples, a size of the conductive structure in the second direction is greater than a distance between the adjacent conductive structures.

In some examples, a ratio of the size of the conductive structure in the second direction to the distance between the adjacent conductive structures is greater than 5:1.

In some examples, the first semiconductor structure further comprises a first contact structure located on a side of the bit line away from the memory cell array and connected to an end of the bit line.

In some examples, a distance between the conductive structure and the bit line is greater than 0.

In some examples, the distance between the conductive structure and the bit line is greater than a pitch between the adjacent bit lines.

In some examples, a gap exists between the conductive structure and the bit line.

In some examples, the gap is an air gap.

In some examples, the peripheral circuit is further connected to the conductive structure and configured to provide a fixed potential to the conductive structure.

In some examples, the second semiconductor structure and the first semiconductor structure are respectively located on different regions of a substrate, or the second semiconductor structure is located between the substrate and the first semiconductor structure, or the second semiconductor structure and the first semiconductor structure are bonded to each other.

According to a third aspect of examples of the present disclosure, a manufacturing method of a semiconductor device is provided, which comprises: forming a plurality of bit lines arranged along a first direction on a side of a transistor; forming a conductive structure on a side of the transistor, wherein the conductive structure comprises a first conductive portion and a second conductive portion, the first conductive portion is located between adjacent bit lines of the plurality of bit lines, the second conductive portion is located on a side of the plurality of bit lines away from the transistor, and the second conductive portion extends along the first direction and is connected to the first conductive portion between the adjacent bit lines.

In some examples, forming the conductive structure on the side of the transistor comprises: forming a spacer layer covering sidewalls of each of the plurality of bit lines and a surface of each of the plurality of bit lines away from the transistor; forming an initial conductive structure covering the transistor and the spacer layer, wherein the initial conductive structure comprises an initial first conductive portion and an initial second conductive portion, the initial first conductive portion is located between adjacent spacer layers and extends along a second direction, the initial second conductive portion extends along the first direction and is connected to the initial first conductive portion between the adjacent spacer layers, and the second direction intersects with the first direction; etching the initial conductive structure to form a plurality of first trenches arranged along the second direction, wherein the first trench exposes the spacer layer of the sidewalls of each of the plurality of bit lines and the surface of each of the plurality of bit lines away from the transistor, the initial first conductive portion between adjacent first trenches of the plurality of first trenches constitutes the first conductive portion, and the initial second conductive portion between the adjacent first trenches constitutes the second conductive portion.

In some examples, the manufacturing method further comprises: removing the exposed spacer layer to form a gap between the bit line and the conductive structure.

In some examples, the manufacturing method further comprises: forming a dielectric layer filling the first trench and covering the second conductive portion; forming a first contact structure extending to the bit line in the dielectric layer, wherein the first contact structure is located between adjacent conductive structures; forming a second contact structure extending to the conductive structure in the dielectric layer, wherein the second contact structure and the first contact structure are spaced apart.

In some examples, forming the conductive structure on the side of the transistor comprises: forming a spacer layer covering sidewalls of each of the plurality of bit lines and a surface of each of the plurality of bit lines away from the transistor; forming the first conductive portion between adjacent spacer layers, wherein the first conductive portion extends along a second direction intersecting with the first direction; removing the spacer layer to form a gap between each of the plurality of bit lines and the first conductive portion; forming a dielectric layer covering the first conductive portion, the gap, and the plurality of bit lines, wherein the dielectric layer has a protrusion toward the bit line; etching the dielectric layer to form a plurality of second trenches arranged along the second direction, wherein a bottom of the second trench exposes the first conductive portion; and forming the second conductive portion in the second trench.

In some examples, a sum of a height of the protrusion and a height of the bit line is equal to a height of the first conductive portion.

In examples of the present disclosure, by disposing the conductive structure comprising the first conductive portion and the second conductive portion on a side of the transistor, the first conductive portion is located between adjacent bit lines, the second conductive portion is located on a side of the plurality of bit lines away from the transistor, and the second conductive portion extends along the first direction and is connected to the first conductive portion between the adjacent bit lines. In this way, the conductive structure can serve as a shielding structure to shield electric energy transfer between the adjacent bit lines, thereby reducing or avoiding coupling between the adjacent bit lines, which facilitates improving sensing margin during reading. In addition, since the sensing margin during reading is improved, a size and/or height of a capacitor is further scaled, which facilitates improving the integration level of the semiconductor device.

### BRIEF DESCRIPTION OF DRAWINGS

In the accompanying drawings, like reference numbers refer to like or similar parts or elements throughout the multiple figures unless otherwise specified. These figures are not necessarily drawn to scale. It should be understood that these figures depict only some implementations disclosed in accordance with the present disclosure and should not be construed as limiting the scope of the present disclosure.

FIG. 1 is a schematic diagram of a memory provided by an exemplary example.

FIG. 2A and FIG. 2B are schematic diagrams of a DRAM provided by an exemplary example.

FIG. 3A and FIG. 3B are schematic diagrams of a semiconductor device provided by an example of the present disclosure.

FIG. 4A and FIG. 4B are schematic diagrams of another semiconductor device provided by an example of the present disclosure.

FIG. 5 is a schematic diagram of a semiconductor device comprising a contact structure provided by an example of the present disclosure.

FIG. 6 is a schematic diagram of another semiconductor device comprising a contact structure provided by an example of the present disclosure.

FIG. 7 is a flowchart of a manufacturing method of a semiconductor device provided by an example of the present disclosure.

FIG. 8 to FIG. 11 are schematic cross-sectional views of a manufacturing process of a semiconductor device provided by an example of the present disclosure.

FIG. 12 to FIG. 15 are schematic cross-sectional views of another manufacturing process of a semiconductor device provided by an example of the present disclosure.

FIG. 16 is a schematic diagram of a memory device provided by an example of the present disclosure.

### DETAILED DESCRIPTION

For ease of understanding of the present disclosure, exemplary implementations of the present disclosure will be described in more detail below with reference to related accompanying drawings. While exemplary implementations of the present disclosure are shown in the drawings, it should be understood that the disclosure may be implemented in various forms and should not be limited by the detailed description set forth herein. Rather, these implementations are provided to enable a more thorough understanding of the present disclosure and to fully convey the scope of the present disclosure to those skilled in the art.

In the following description, numerous specific details are given in order to provide a more thorough understanding of the present disclosure. It will be apparent to those skilled in the art, however, that the present disclosure may be implemented without one or more of these details. In some examples, in order to avoid confusion with the present disclosure, some technical features known in the art are not described; that is, all features of the actual examples may not be described herein, and well-known functions and structures are not described in detail.

In general, the terms may be understood at least in part from the use in context. For example, depending at least in part on context, the term “one or more” as used herein may be used to describe any feature, structure, or characteristic in a singular sense, or may be used to describe a combination of features, structures, or characteristics in a plural sense. Similarly, terms such as “a”, “an” or “the”, again, may be understood to convey singular usage or to convey plural usage, depending at least in part on context. In addition, term “based on” may be understood as not necessarily intended to convey an exclusive set of factors, and may, instead, allow for the presence of additional factors not necessarily expressly described, again, depending at least in part on context.

Unless otherwise defined, the terminology used herein is for the purpose of describing particular examples only and is not limiting of the present disclosure. As used herein, the singular forms “a,” “an,” and “the” are intended to comprise a plural form as well, unless otherwise clearly indicated in context. It should also be understood that the terms “consist of” and/or “comprise”, when used in this specification, determine the presence of stated features, integers, steps, operations, elements, and/or components, but do not preclude the presence or addition of one or more other features, integers, steps, operations, elements, components, and/or groups. As used herein, the term “and/or” comprises any and all combinations of related listed items.

For a thorough understanding of the present disclosure, detailed steps and detailed structures will be presented in the following description in order to explain the technical solutions of the present disclosure. Preferred examples of the present disclosure are described in detail as below, however, other implementations may be provided in the present disclosure in addition to these detailed descriptions.

Before describing the examples of the present disclosure, various directions that may be involved in the following description are first defined. A first direction (denoted as x direction in the figures) and a second direction (denoted as y direction in the figures) that intersect with each other are defined in a plane parallel to a substrate, and a direction perpendicular to the plane of the substrate is defined as a third direction (denoted as z direction in the figures). The x direction intersects with the y direction, and the included angle between the x direction and the y direction comprises an acute angle, a right angle, or an obtuse angle. For ease of understanding, the following takes the included angle between the x direction and the y direction being a right angle as an example, that is, any two of the x direction, the y direction, and the z direction are perpendicular to each other. As used in the present disclosure, “height” refers to a size of a certain structure or a certain film layer in the z direction, which will not be repeated hereinafter for the sake of brevity.

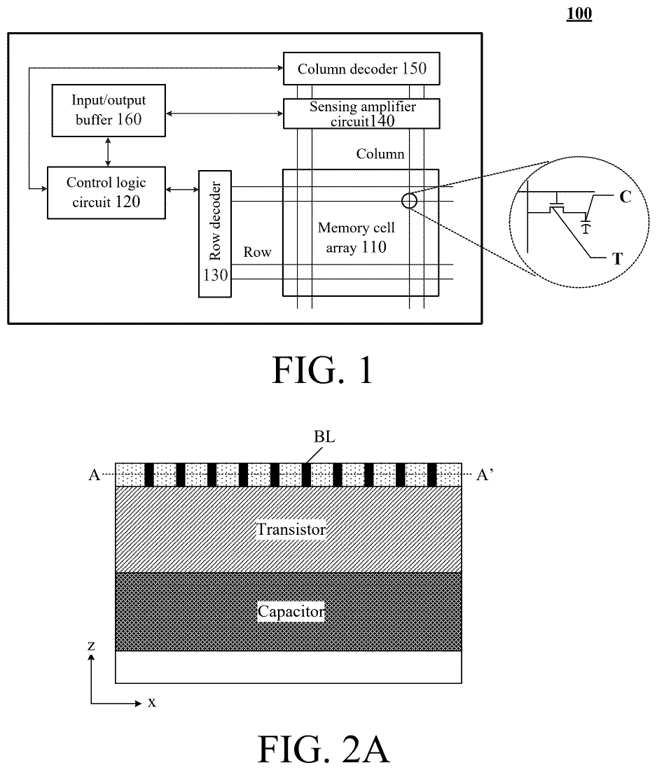

FIG. 1 is a schematic diagram of a memory provided by an exemplary example. Referring to FIG. 1, the memory 100 comprises a memory cell array 110 which comprises a plurality of memory cells arranged in an array, each memory cell comprises a transistor T and a capacitor C, and the main operating principle of the memory cell is to use the amount of charges stored in the capacitor to represent whether one binary bit is 1 or 0.

The memory cell array 110 may be divided into a plurality of memory banks, each memory bank comprises a plurality of memory blocks, each memory block comprises a plurality of rows of memory cells and a plurality of columns of memory cells, each row of memory cells is coupled to one corresponding word line, and each column of memory cells is coupled to one corresponding bit line. The memory cell array 110 specifies addresses using row and column. By specifying the intersection of row and column (by specifying the row address and column address of the DRAM), the memory controller may independently access individual memory cells and read, write, or refresh the data stored therein.

Still referring to FIG. 1, the memory 100 further comprises a peripheral circuitry coupled to the memory cell array 110, the peripheral circuitry may write data to or read data from the memory cell array 110 in response to a command CMD and an address ADDR received from the memory controller, or may provide control signals for refreshing memory cells included in the memory cell array 110 to a row decoder 130 and a column decoder 150. In other words, the peripheral circuitry may perform all operations to process data in the memory cell array 110. The peripheral circuit may comprise: a control circuit corresponding to each memory block, such as a sensing amplifier circuit 140 and a word line driver circuit (not shown), and the like; a control circuit corresponding to each memory bank, such as a row decoder 130, a column decoder 150, and the like; and a control circuit corresponding to all memory banks, such as an input/output buffer 160, a command buffer, a command decoder, an address buffer, a mode register, and the like.

The memory 100 may be a Random Access Memory (RAM), such as DRAM, synchronous DRAM (SDRAM), SRAM, double data rate SDRAM (DDR SDRAM), DDR2 SDRAM, DDR3 SDRAM, phase change RAM (PRAM), magnetic RAM (MRAM), resistive RAM (RRAM), or the like. The following uses the memory 100 being DRAM only as an example for description.

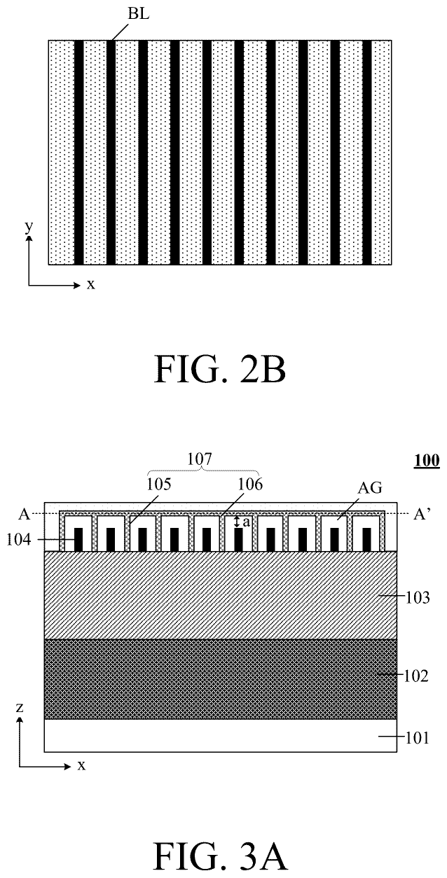

FIG. 2A and FIG. 2B are schematic diagrams of a DRAM provided by an exemplary example, where FIG. 2A is a schematic cross-sectional view of the DRAM, and FIG. 2B is a schematic top view taken along the dashed line AA′ in FIG. 2A. Referring to FIG. 2A, the DRAM comprises a capacitor, a transistor and a bit line BL, where the capacitor and the bit line BL are respectively disposed on two sides of the transistor, for example, two opposite sides along the z direction. In an example, the transistor may be a vertical transistor, that is, an extension direction of an active region of the transistor is perpendicular to horizontal plane, for example, the extension direction of the active region is perpendicular to xy plane, the bit line BL is connected to a drain of the transistor, the capacitor is connected to a source of the transistor, the word line (not shown in the figure) is connected to a gate of the transistor, the on or off of the transistor may be controlled by controlling a word line voltage applied to the word line, so that the data stored in the capacitor can be read or the data can be written into the capacitor through the bit line BL.

Referring to FIG. 2B, the plurality of bit lines BL are arranged along the x direction, adjacent bit lines BL are isolated by a dielectric layer, each bit line BL extends along the y direction, and each bit line BL can connect drains of a plurality of transistors arranged along the y direction. It can be understood that the plurality of transistors may be arranged in an array in the x direction and the y direction, so as to form a plurality of memory units arranged in an array.

With the iteration of DRAM products, a bit line pitch (BL pitch) and a word line pitch (WL pitch) are continuously decreased, resulting in that the overall coupling of the device is continuously improved, and the presence of parasitic capacitance causes sensing margin during reading to decrease. In addition, a size of the capacitor is also continuously decreased, and due to the limitation of the limit of the etching machine table, the height of the capacitor also decreases as the size of the capacitor decreases, so that the capacitance value of the capacitor continuously decreases, which also causes the sensing margin during reading to decrease.

Based on one or more of the above technical problems, an example of the present disclosure provides a semiconductor device.

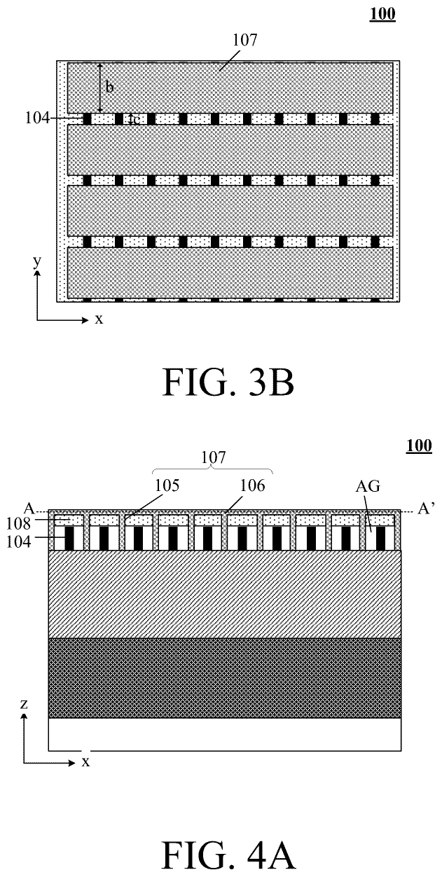

FIG. 3A and FIG. 3B are schematic diagrams of a semiconductor device provided by an example of the present disclosure, where FIG. 3A is a schematic cross-sectional view of the semiconductor device, and FIG. 3B is a schematic top view taken along the dashed line AA in FIG. 3A. The semiconductor device comprises, but is not limited to, DRAM.

Referring to FIG. 3A and FIG. 3B, the semiconductor device 100 comprises a plurality of bit lines 104 and a conductive structure 107, the plurality of bit lines 104 are located on a side of the transistor and are arranged along a first direction, the conductive structure 107 is located on a side of the transistor and comprises a first conductive portion 105 and a second conductive portion 106, the first conductive portion 105 is located between adjacent bit lines 104, and the second conductive portion 106 is located on a side of the plurality of bit lines 104 away from the transistor, wherein the second conductive portion 106 extends along the first direction and is connected to the first conductive portion 105 between the adjacent bit lines 104.

Referring to FIG. 3A, the semiconductor device 100 may further comprise a substrate 101, a first dielectric layer 102, and a second dielectric layer 103. A material of the substrate 101 comprises a semiconductor material, for example, an elemental semiconductor material (e.g., silicon (Si) or germanium (Ge), etc. ), a III-V compound semiconductor material (e.g., gallium nitride (GaN), gallium arsenide (GaAs), or indium phosphide (InP), etc. ), a II-VI compound semiconductor material (e.g., zinc sulfide (ZnS), cadmium sulfide (CdS), or cadmium telluride (CdTe), etc. ), an organic semiconductor material, or other semiconductor material known in the art. Each of a material of the first dielectric layer 102 and a material of the second dielectric layer 103 comprises a dielectric material, for example, at least one of silicon oxide, silicon nitride, and silicon oxynitride.

A capacitor array (not shown in the figure) may be formed in the first dielectric layer 102, and a transistor array (not shown in the figure) may be formed in the second dielectric layer 103. The capacitor array may comprise a plurality of capacitors arranged in an array along the x direction and the y direction, the transistor array may comprise a plurality of transistors arranged in an array along the x direction and the y direction, one transistor may be connected to one corresponding capacitor, and the plurality of capacitors and the plurality of transistors may constitute a plurality of memory units arranged in an array. The transistor comprises, but is not limited to, a vertical transistor, and the gate type of the vertical transistor may be any one of a single gate, a double gate, a triple gate, and a gate all around. By providing a vertical transistor connected to the capacitor, the integration level of the semiconductor device 100 can be improved.

Referring to FIG. 3A, the plurality of bit lines 104 are located on a side of the second dielectric layer 103 away from the first dielectric layer 102 and are arranged along the x direction, that is, the plurality of bit lines 104 are located on a side of the transistor and are arranged along the x direction. Referring to FIG. 3B, each bit line 104 extends along the y direction, and each bit line 104 may be connected to one end (for example, the drain of the transistor) of a plurality of transistors arranged along the y direction, that is, a plurality of memory cells arranged along the y direction are connected to the same bit line 104. A material of the bit line 104 comprises a conductive material, for example, at least one of polysilicon, doped polysilicon, metal (e.g., tungsten, titanium, tantalum, etc.), metal silicide (e.g., tungsten silicide, titanium silicide, etc.), metal nitride (e.g., tungsten nitride, tantalum nitride, etc.).

Referring to FIG. 3A, the conductive structure 107 is located on a side of the second dielectric layer 103 away from the first dielectric layer 102, that is, the conductive structure 107 and the bit line 104 are located on the same side of the transistor, and it should be noted that the conductive structure 107 and the bit line 104 are isolated from each other. Specifically, the conductive structure 107 comprises a first conductive portion 105 and a second conductive portion 106, the first conductive portion 105 extends until it is between adjacent bit lines 104, that is, the first conductive portion 105 is located between adjacent bit lines 104, the second conductive portion 106 is located on a side of the plurality of bit lines 104 away from the transistor, and the second conductive portion 106 extends along the first direction and is connected to the first conductive portion 105 between adjacent bit lines 104. Here, the second conductive portion 106 may be connected to one or more first conductive portions 105, and the number of the first conductive portions 105 may be set reasonably according to the actual number of the bit lines 104 in semiconductor device 100, which is not particularly limited in the present disclosure.

During operation of the semiconductor device 100, a fixed potential (e.g., ground level VSS) may be provided to the conductive structure 107, that is, the conductive structure 107 is configured to be connected to a fixed potential. The fixed potential provided to the conductive structure 107 can shield electric energy transfer between adjacent bit lines 104, thereby reducing or avoiding coupling between the adjacent bit lines 104, which facilitates improving the sensing margin during reading. In addition, since the sensing margin during reading is improved, the size and/or height of the capacitor is further scaled, which facilitates improving the integration level of the semiconductor device 100. It can be understood that, in examples of the present disclosure, the conductive structure 107 may serve as a shielding structure, and the fixed potential comprises, but is not limited to, the ground level VSS, and any electric potential capable of shielding electric energy transfer between adjacent conductors should be covered within the protection scope of the present disclosure.

In some examples, a height of the first conductive portion 105 is greater than a height of the bit line 104. For example, referring to FIG. 3A, a surface of the first conductive portion 105 relatively close to the second dielectric layer 103 is flush with a surface of the bit line 104 relatively close to the second dielectric layer 103, a surface of the first conductive portion 105 relatively away from the second dielectric layer 103 is higher than a surface of the bit line 104 relatively away from the second dielectric layer 103, so that the height of the first conductive portion 105 is greater than the height of the bit line 104, and thus, the second conductive portion 106 may be prevented from contacting the bit line 104.

In some examples, a distance between the second conductive portion 106 and the bit line 104 is greater than 0. For example, referring to FIG. 3A, a >0, a represents the distance between the second conductive portion 106 and the bit line 104. In an example, a is equal to a height difference between a surface of the second conductive portion 106 relatively close to the second dielectric layer 103 and a surface of the bit line 104 relatively away from the second dielectric layer 103.

In some examples, a distance between the second conductive portion 106 and the bit line 104 is greater than a pitch between adjacent bit lines 104, that is, a >bit line pitch. It should be noted that the bit line pitch may be equal to a sum of a bit line width and a bit line spacing, the bit line width represents a size of a certain bit line in the x direction, and the bit line spacing represents a spacing between adjacent bit lines. In an example, the bit line pitch may be a distance between same side edges of the adjacent bit lines, for example, a distance between left side edges of the adjacent bit lines or a distance between right side edges of the adjacent bit lines. In another example, the bit line pitch may be a distance between centers of the adjacent bit lines.

In some examples, referring to FIG. 3A, a gap exists between the conductive structure 107 and the bit line 104, so that the conductive structure 107 and the bit line 104 can be isolated from each other by the gap. Here, a closed gap may be defined through the conductive structure 107, the bit line 104, and dielectric layers (not shown in the figure) disposed on two opposite sides of the conductive structure 107 along the y direction. In an example, the gap is an air gap AG. Since the dielectric constant of air is small, not only the coupling between the adjacent bit lines 104 can be reduced or avoided, but also coupling between the bit line 104 and the conductive structure 107 can be reduced.

In some examples, the semiconductor device 100 comprises a plurality of conductive structures 107 arranged along a second direction intersecting with the first direction. For example, referring to FIG. 3B, the plurality of conductive structures 107 are arranged along the y direction, adjacent conductive structures 107 are isolated from each other, and a dielectric layer may be filled between the adjacent conductive structures 107. During operation of the semiconductor device 100, a fixed potential may be provided to the plurality of conductive structures 107, for example, each of the plurality of conductive structures 107 is grounded, thereby further shielding the electric energy transfer between the adjacent bit lines 104 and between the bit lines 104 and conductive structures 107, which may further reduce or avoid the coupling between the adjacent bit lines 104 and between the bit lines 104 and conductive structures 107, so that the sensing margin during reading is greatly improved.

In some examples, a size of the conductive structure 107 in the second direction is greater than a distance between adjacent conductive structures 107. For example, referring to FIG. 3B, b >c, b represents a size of the conductive structure 107 in the y direction, and c represents a distance between adjacent conductive structures 107.

In an example, a ratio of the size of the conductive structure 107 in the second direction to the distance between the adjacent conductive structures 107 is greater than 5:1, that is, a ratio of b to c is greater than 5, so that the proportion of conductive structures 107 per unit area is relatively large, thereby enhancing the shielding effect of the conductive structure 107.

According to examples of the present disclosure, by disposing the conductive structure 107 between the adjacent bit lines 104, while disposing an air gap AG between the conductive structure 107 and the bit line 104, not only the coupling between the adjacent bit lines 104 (that is, the coupling in the x direction) can be reduced, but also the coupling between the bit line 104 and the conductive structure 107 (that is, the coupling in the y direction) can be reduced, so that the coupling in the x direction and the coupling in the y direction are at an appropriate level, thereby improving the sensing margin during reading.

It should be noted that, by adjusting the values of b and c, the coupling between the bit line 104 and the conductive structure 107 may be adjusted. Specifically, the smaller the value of c, the larger the coupling between the bit line 104 and the conductive structure 107; in contrast, the larger the value of c, the smaller the coupling between the bit line 104 and the conductive structure 107. Therefore, in practical applications, the above three parameters a, b and c may be reasonably adjusted according to design requirements to adjust the sensing margin during reading to an optimal level, for example, b may be designed to be much larger than c, and the larger the value of a, the better.

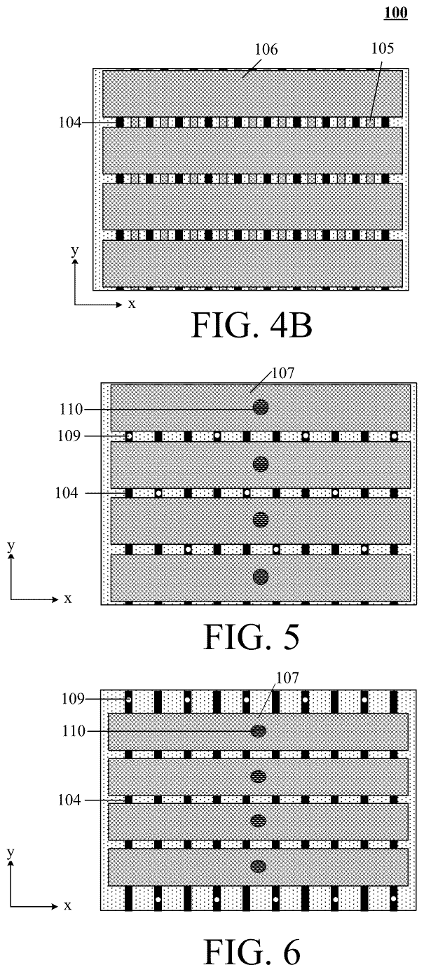

FIG. 4A and FIG. 4B are schematic diagrams of another semiconductor device provided by an example of the present disclosure, where FIG. 4A is a schematic cross-sectional view of the semiconductor device, and FIG. 4B is a schematic top view taken along the dashed line AA′ in FIG. 4A. It should be noted that the structures in the examples shown in FIG. 4A and FIG. 4B same as those in the above examples continue to use the same reference numerals, and the same structures may refer to the related description of the above examples, and are not described in detail again. In this example, only different structures are described in detail. Referring to FIGS. 4A and 4B, the first conductive portions 105 of the plurality of conductive structures 107 extend along the second direction and are connected to each other.

For example, referring to FIG. 4A, each second conductive portion 106 is connected to a plurality of first conductive portions 105, the plurality of first conductive portions 105 connected to each second conductive portion 106 are arranged along the x direction, and the plurality of first conductive portions 105 connected to each second conductive portion 106 are respectively located between adjacent bit lines 104, that is, the plurality of bit lines 104 and the plurality of first conductive portions 105 are alternately arranged along the x direction.

For example, referring to FIG. 4B, the first conductive portions 105 located between adjacent bit lines 104 extend along the y direction and are respectively connected to the second conductive portions 106 of the plurality of conductive structures 107, that is, the first conductive portions 105 of the plurality of conductive structures 107 extend along the second direction and are connected to each other, for example, the first conductive portions 105 of the plurality of conductive structures 107 are connected to each other under the second conductive portions 106. It can be understood that, in FIG. 3B, the plurality of first conductive portions 105 located between adjacent bit lines 104 and respectively connected to corresponding second conductive portions 106 are spaced apart from each other.

In examples of the present disclosure, by disposing the first conductive portions 105 of the plurality of conductive structures 107 to extend along the second direction and be connected to each other, the shielding effect of conductive structures 107 may be enhanced.

FIG. 5 is a schematic diagram of a semiconductor device comprising a contact structure provided by an example of the present disclosure. It should be noted that the structures in the example shown in FIG. 5 same as those in the above examples continue to use the same reference numerals, and the same structures may refer to the related description of the above examples, and are not described in detail again. In this example, only different structures are described in detail.

Referring to FIG. 5, the semiconductor device 100 further comprises a first contact structure 109 and a second contact structure 110, the first contact structure 109 is located on a side of the bit line 104 away from the transistor and is connected to the bit line 104, wherein the first contact structure 109 is located between adjacent conductive structures 107; the second contact structure 110 is located on a side of the conductive structure 107 away from the bit line 104 and is connected to the conductive structure 107, wherein the second contact structure 110 and the first contact structure 109 are spaced apart.

The first contact structure 109 is configured to electrically lead out the bit line 104, the second contact structure 110 is configured to electrically lead out the conductive structure 107, and each of the number of the first contact structure 109 and the number of the second contact structure 110 can be one or more. For example, referring to FIG. 5, in a case where the semiconductor device 100 comprises a plurality of bit lines 104 and a plurality of conductive structures 107, each of the number of the first contact structure 109 and the number of the second contact structure 110 can be more, each first contact structure 109 is connected to one bit line 104, and each second contact structure 110 is connected to one conductive structure 107.

Each of a material of the first contact structure 109 and a material of the second contact structure 110 comprises a conductive material, such as at least one of polysilicon, doped polysilicon, metal (e.g., tungsten, titanium, tantalum, etc.), metal silicide (e.g., tungsten silicide, titanium silicide, etc.), metal nitride (e.g., tungsten nitride, tantalum nitride, etc.). The material of the first contact structure 109 and the material of the second contact structure 110 may be the same or different, which is not particularly limited in the present disclosure.

In examples of the present disclosure, the first contact structure 109 may extend through the dielectric layer between the adjacent conductive structures 107 until it is connected to the bit line 104, and the second contact structure 110 may extend through a dielectric layer covering the second conductive portion 106 until it is connected to the second conductive portion 106, so that the arrangement of the first contact structure 109 and the second contact structure 110 in the semiconductor device 100 can be optimized.

In some examples, the plurality of first contact structures 109 are alternately arranged. For example, referring to FIG. 5, adjacent first contact structures 109 are respectively located on two opposite sides of the conductive structure 107 along the y direction, so that a distance between the adjacent first contact structures 109 can be increased, and coupling between the adjacent first contact structures 109 can be reduced.

In some examples, the plurality of second contact structures 110 are respectively connected to the plurality of conductive structures 107, wherein the plurality of second contact structures 110 are connected to each other. For example, in a case where each of the plurality of conductive structures 107 is configured to be connected to the same fixed potential (e.g., the ground level VSS), the plurality of second contact structures 110 leading out the plurality of conductive structures 107 can be connected to each other, thereby simplifying the operation of the semiconductor device 100. Of course, in other examples, the plurality of conductive structures 107 may be separately led out.

FIG. 6 is a schematic diagram of another semiconductor device comprising a contact structure provided by an example of the present disclosure. It should be noted that the structures in the example shown in FIG. 6 same as those in the above examples continue to use the same reference numerals, and the same structures may refer to the related description of the above examples, and are not described in detail again. In this example, only different structures are described in detail.

Referring to FIG. 6, the semiconductor device 100 further comprises a first contact structure 109 located on a side of the bit line 104 away from the transistor and connected to an end of the bit line 104. The bit line 104 may comprise a first end and a second end opposite to each other along the y direction, the first contact structure 109 may extend through a dielectric layer covering the first end of the bit line 104 until it is connected to the first end of the bit line 104, or the first contact structure 109 may extend through a dielectric layer covering the second end of the bit line 104 until it is connected to the second end of the bit line 104, so that the bit line 104 can be electrically led out.

In some examples, the plurality of first contact structures 109 are alternately arranged. For example, referring to FIG. 6, adjacent first contact structures 109 are respectively located on two opposite outer sides of the plurality of conductive structures 107 along the y direction, one of the adjacent first contact structures 109 is connected to the first end of one of the adjacent bit lines, and the other one of the adjacent first contact structures 109 is connected to the second end of the other one of the adjacent bit lines. In this way, the distance between the adjacent first contact structures 109 can be increased, and the coupling between the adjacent first contact structures 109 and coupling between the first contact structures 109 and conductive structures 107 can be reduced.

Based on the above semiconductor device, an example of the present disclosure provides a manufacturing method of a semiconductor device. The manufacturing method can be used for manufacturing the semiconductor device in any of the above examples.

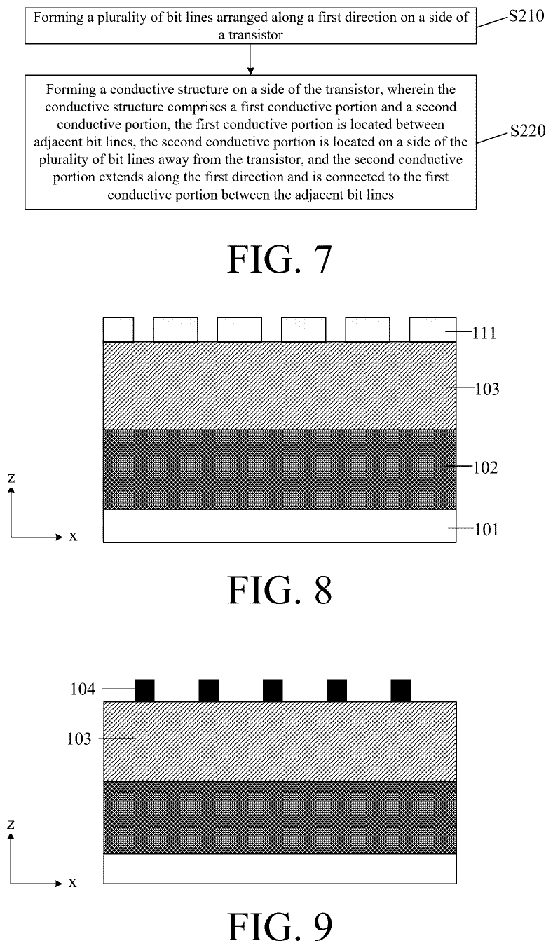

FIG. 7 is a flowchart of a manufacturing method of a semiconductor device provided by an example of the present disclosure. It should be noted that the operations shown in FIG. 7 are not exclusive, and other operations may be performed before, after, or between any operations in the illustrated operations; the order of the operations shown in FIG. 7 may be adjusted according to actual needs. Referring to FIG. 7, the manufacturing method comprises at least the following operations:
Operation S210: forming a plurality of bit lines arranged along a first direction on a side of a transistor;
Operation S220: forming a conductive structure on a side of the transistor; wherein the conductive structure comprises a first conductive portion and a second conductive portion, the first conductive portion is located between adjacent bit lines, and the second conductive portion is located on a side of the plurality of bit lines away from the transistor; and the second conductive portion extends along the first direction and is connected to the first conductive portion between the adjacent bit lines.

In examples of the present disclosure, by forming the conductive structure comprising the first conductive portion and the second conductive portion on a side of the transistor, the first conductive portion is located between adjacent bit lines, the second conductive portion is located on a side of the plurality of bit lines away from the transistor, and the second conductive portion extends along the first direction and is connected to the first conductive portion between the adjacent bit lines. In this way, the conductive structure can serve as a shielding structure to shield electric energy transfer between adjacent bit lines, thereby reducing or avoiding coupling between adjacent bit lines, which facilitates improving the sensing margin during reading. In addition, since the sensing margin during reading is improved, the size and/or height of the capacitor is further scaled, which facilitates improving the integration level of the semiconductor device.

FIG. 8 to FIG. 11 are schematic cross-sectional views of a manufacturing process of a semiconductor device provided by an example of the present disclosure, and the manufacturing method of the semiconductor device provided by the example of the present disclosure will be exemplarily described below in conjunction with FIG. 7 and FIG. 8 to FIG. 11. In operation S210, a plurality of bit lines 104 arranged along a first direction are formed on a side of a transistor, as shown in FIG. 9.

The process of forming the plurality of bit lines 104 comprises: forming a sacrificial layer 111 on a side of a second dielectric layer 103 away from a first dielectric layer 102, performing a patterning process on the sacrificial layer 111 to form a plurality of bit line trenches extending through the sacrificial layer 111, the plurality of bit line trenches are arranged along the x direction, and each of the bit line trenches extending along the y direction, as shown in FIG. 8; filling the plurality of bit line trenches with a conductive material to form a plurality of bit lines 104, as shown in FIG. 9. In practical applications, a planarization process may be performed on the conductive material until the sacrificial layer 111 is exposed, and then the sacrificial layer 111 is removed, thereby forming the plurality of bit lines 104 spaced apart as shown in FIG. 9. The patterning process comprises a photolithography process and an etching process, and the planarization process comprises, but are not limited to, chemical mechanical polishing process.

In some examples, referring to FIG. 8, the manufacturing method further comprises: providing a substrate 101; forming a first dielectric layer 102 on a side of the substrate 101, and forming a capacitor array in the first dielectric layer 102; forming the second dielectric layer 103 on a side of the first dielectric layer 102 away from the substrate 101, and forming a transistor array in the second dielectric layer 103. For the capacitor array and the transistor array, reference may be made to the related description of the above examples, and they are not described in detail here again.

In operation S220, a conductive structure 107 is formed on a side of the transistor, the conductive structure 107 and the bit line 104 may be located on the same side of the transistor, and the conductive structure 107 and the bit line 104 are isolated from each other, as shown in FIG. 11.

In some examples, referring to FIG. 10 and FIG. 11, the above operation S220 comprises: forming a spacer layer 112 covering sidewalls of each bit line 104 and a surface of each bit line 104 away from the transistor; forming an initial conductive structure 107S covering the transistor and the spacer layer 112, wherein the initial conductive structure 107S comprises an initial first conductive portion 105S and an initial second conductive portion 106S, the initial first conductive portion 105S is located between adjacent spacer layers 112 and extends along the second direction, the initial second conductive portion 106S extends along the first direction and is connected to the initial first conductive portion 105S between the adjacent spacer layers 112, and the second direction intersects with the first direction; etching the initial conductive structure 107S to form a plurality of first trenches arranged along the second direction, wherein the first trench exposes the spacer layer 112 of the sidewalls of each bit line 104 and the surface of each bit line 104 away from the transistor, the initial first conductive portion 105S between adjacent first trenches constitutes a first conductive portion 105, and the initial second conductive portion 106S between adjacent first trenches constitutes a second conductive portion 106.

For example, an initial spacer layer may be deposited on the basis of the structure shown in FIG. 9, the initial spacer layer covers the exposed surface of the second dielectric layer 103, sidewalls of each bit line 104 and a surface of each bit line 104 relatively away from the second dielectric layer 103, and a deposition process of the initial spacer layer comprises, but is not limited to, an atomic layer deposition process. A portion of the initial spacer layer is removed by etching along a direction toward the surface of the second dielectric layer 103, and the remaining initial spacer layer constitutes the spacer layer 112 as shown in FIG. 10. A material of the spacer layer 112 comprises at least one of silicon oxide, silicon nitride, and silicon oxynitride. In some examples, a material of the spacer layer 112 and a material of the second dielectric layer 103 are different, for example, the material of the second dielectric layer 103 is silicon oxide, and the material of the spacer layer 112 is silicon nitride.

For example, the initial conductive structure 107S may be deposited on the basis of forming the spacer layer 112 as shown in FIG. 10, and the initial conductive structure 107S comprises the initial first conductive portion 105S filled between adjacent spacer layers 112 and the initial second conductive portion 106S covering the initial first conductive portion 105S and the spacer layer 112, as shown in FIG. 10. The initial conductive structure 107S may be selectively etched to form a plurality of first trenches arranged along the y direction, and the plurality of first trenches may divide the initial conductive structure 107S into a plurality of conductive structures 107, as shown in FIG. 3B. It can be understood that the plurality of first trenches divide the initial first conductive portion 105S between adjacent bit lines 104 into a plurality of first conductive portions 105 arranged along the y direction, and the plurality of first conductive portions 105 arranged along the y direction respectively correspond to different conductive structures 107; the plurality of first trenches divide the initial second conductive portion 106S covering the initial first conductive portion 105S and the spacer layer 112 into a plurality of second conductive portions 106 arranged along the y direction, and each second conductive portion 106 is connected the plurality of first conductive portions 105 arranged in the x direction, that is, each first trench exposes a surface of the second dielectric layer 103 between the first conductive portions 105 adjacent along the y direction and a portion of the spacer layer 112.

In some examples, the manufacturing method further comprises: removing the exposed spacer layer 112 to form a gap AG between the bit line 104 and the conductive structure 107. Here, the exposed spacer layer 112 may be removed through the first trench, then a dielectric material is deposited into the first trench, and by controlling the deposition rate of the dielectric material, a top of the first trench may be sealed in advance, thereby forming the gap AG between the bit line 104 and the conductive structure 107.

In some examples, the manufacturing method further comprises: forming a dielectric layer filling the first trench and covering the second conductive portion; forming a first contact structure extending to the bit line 104 in the dielectric layer, wherein the first contact structure is located between adjacent conductive structures 107; forming a second contact structure extending to the conductive structure 107 in the dielectric layer, wherein the second contact structure and the first contact structure are spaced apart.

For example, by controlling the deposition duration of the dielectric material, the dielectric material may be made to cover the second conductive portion 106, that is, a dielectric layer filling the first trench and covering the second conductive portion 106 is formed. The dielectric layer between adjacent conductive structures 107 is etched to form a first contact hole extending through the dielectric layer, a bottom of the first contact hole exposes the bit line 104, and the first contact hole is filled with a conductive material, thereby forming a first contact structure extending to the bit line 104 in the dielectric layer; the dielectric layer covering the second conductive portion is etched to form a second contact hole extending through the dielectric layer, a bottom of the second contact hole exposes the second conductive portion, and the second contact hole is filled with a conductive material, thereby forming a second contact structure extending to the conductive structure 107 in the dielectric layer.

In some examples, the first contact hole and the second contact hole are etched simultaneously, so that the number of processes can be reduced, and the first contact hole and the second contact hole can adopt the same mask, thereby saving the production cost. Of course, in other examples, the first contact hole and the second contact hole may also be etched separately.

It can be understood that the semiconductor device shown in FIGS. 3A-3B can be formed by performing a manufacturing process similar to that of FIG. 8 to FIG. 11.

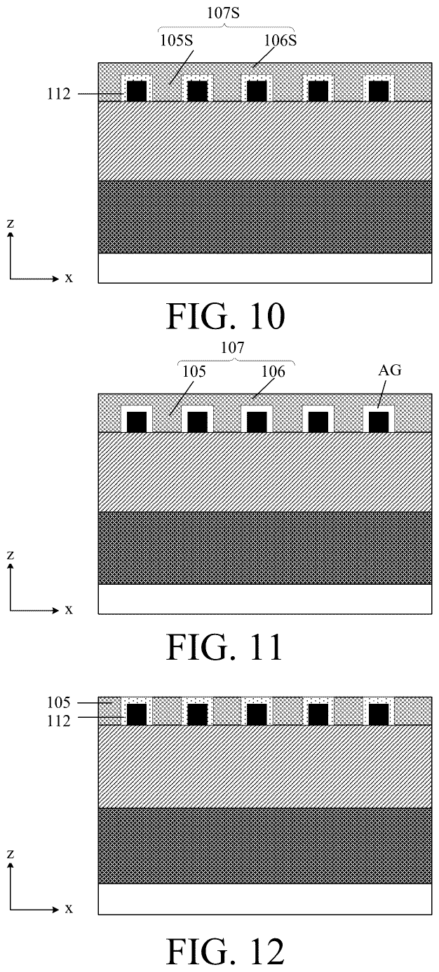

FIG. 12 to FIG. 15 are schematic cross-sectional views of another manufacturing process of a semiconductor device provided by an example of the present disclosure, and the manufacturing method of the semiconductor device provided by the example of the present disclosure will be exemplarily described below in conjunction with FIG. 7 and FIG. 12 to FIG. 15.

In operation S210, a plurality of bit lines 104 arranged along a first direction are formed on a side of a transistor. For the process of forming the plurality of bit lines 104, reference may be made to the related description of the above examples, and it is not described in detail here again.

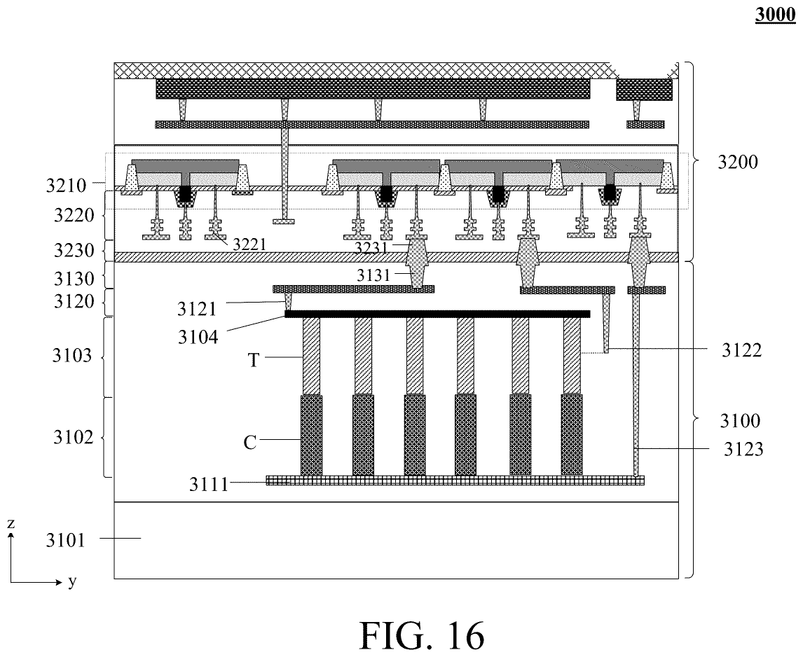

In operation S220, a conductive structure 107 is formed on a side of the transistor, the conductive structure 107 and the bit line 104 may be located on the same side of the transistor, and the conductive structure 107 and the bit line 104 are isolated from each other, as shown in FIG. 15. A dielectric layer 108 is formed between the bit line 104 and the second conductive portion in FIG. 15, and a gap is located between the first conductive portion 105 and the bit line 104.

In some examples, referring to FIG. 12 to FIG. 15, the above operation S220 comprises: forming a spacer layer 112 covering sidewalls of each bit line 104 and a surface of each bit line 104 away from the transistor; forming a first conductive portion 105 between adjacent spacer layers 112, wherein the first conductive portion 105 extends along the second direction intersecting with the first direction; removing the spacer layer 112 to form a gap between each bit line 104 and the first conductive portion 105; forming a dielectric layer 108 covering the first conductive portion 105, the gap, and the plurality of bit lines 104, wherein the dielectric layer 108 has a protrusion toward the bit line 104; etching the dielectric layer 108 to form a plurality of second trenches arranged along the second direction, wherein a bottom of the second trench exposes the first conductive portion 105; and forming a second conductive portion 106 in the second trench.

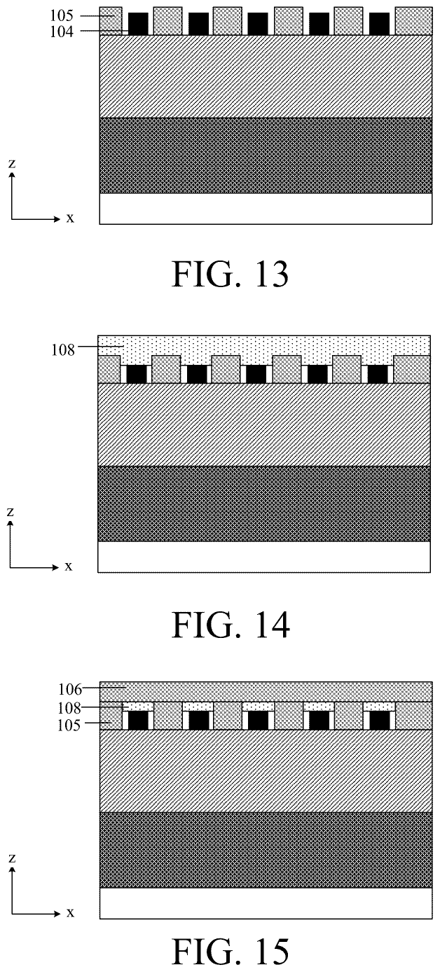

For example, the first conductive portion 105 may be deposited on the basis of forming the spacer layer 112 as shown in FIG. 12, and the first conductive portion 105 is formed between the adjacent spacer layers 112 and extends along the y direction, as shown in FIG. 12. For the process of forming the spacer layer 112, reference may be made to the related description of the above examples, and it is not described in detail here again. Here, a planarization process may be performed on the first conductive portion until the spacer layer 112 is exposed, thereby forming a first conductive portion that is flush with the spacer layer 112. After the first conductive portion 105 is formed, the spacer layer 112 may be selectively removed, thereby forming an initial gap between each bit line 104 and the first conductive portion 105, as shown in FIG. 13.

For example, a dielectric material may be deposited on the basis of the structure shown in FIG. 13, by controlling the deposition rate of the dielectric material, the exposed initial gap may be sealed in advance, thereby forming a gap between each bit line 104 and the first conductive portion 105, as shown in FIG. 14, and by controlling the deposition duration of the dielectric material, the dielectric material may be made to cover the first conductive portion 105, the gap, and the plurality of bit lines 104, that is, forming the dielectric layer 108 covering the first conductive portion 105, the gap, and the plurality of bit lines 104, and the dielectric layer 108 has a protrusion toward the bit line 104, as shown in FIG. 14. The dielectric layer 108 may be selectively etched to form a plurality of second trenches arranged along the y direction, a bottom of each second trench exposes the first conductive portion 105, a conductive material is filled into the second trench, the second conductive portion 106 as shown in FIG. 15 may be formed, the second conductive portion 106 is connected to the plurality of first conductive portions 105 arranged along the x direction, and a protrusion of the dielectric layer 108 is located between the bit line 104 and the second conductive portion 106.

In some examples, referring to FIG. 15, a sum of a height of the protrusion and a height of the bit line 104 is equal to a height of the first conductive portion 105.

It can be understood that the semiconductor device shown in FIGS. 4A-4B can be formed by performing a manufacturing process similar to that of FIG. 12 to FIG. 15.

Based on the above semiconductor device, an example of the present disclosure provides a memory device. The memory device comprises a first semiconductor structure and a second semiconductor structure, the first semiconductor structure comprises a memory cell array, a plurality of bit lines and a conductive structure, the plurality of bit lines are located on a side of the memory cell array and are arranged along a first direction, the conductive structure extends along the first direction and covers at least a portion of the bit line, the second semiconductor structure comprises a peripheral circuit connected to the memory cell array through the plurality of bit lines.

FIG. 16 is a schematic diagram of a memory device provided by an example of the present disclosure. Referring to FIG. 16, the memory device 3000 comprises a first semiconductor structure 3100 and a second semiconductor structure 3200, which may be vertically connected by bonding. The bonding connection comprises a hybrid bonding connection (also referred to as a “metal/dielectric hybrid bonding connection”), which is a direct bonding technology (e.g., forming bonding between surfaces without using intermediate layer such as solder or adhesive) and can obtain metal-metal bonding and dielectric-dielectric bonding simultaneously. It should be noted that the “bonding” mentioned in the present disclosure may be any suitable bonding technique, such as hybrid bonding, anodic bonding, fusion bonding, transfer bonding, adhesive bonding, eutectic bonding, and the like.

The first semiconductor structure 3100 comprises a substrate 3101, a first dielectric layer 3102, a second dielectric layer 3103, a plurality of bit lines 3104, a conductive structure, a first interconnect layer 3120, and a first bonding layer 3130. For the substrate 3101, reference may be made to the substrate 101 in the above examples. In an example, the substrate 3101 may be a silicon substrate with one or more film layers formed thereon, that is, the first dielectric layer 3102 is formed on a front side of the silicon substrate. In other examples, the substrate 3101 may be a carrier wafer for flip-chip bonding.

The first dielectric layer 3102 is located on a side of the substrate 3101, a capacitor array is disposed in the first dielectric layer 3102, the capacitor array may comprise a plurality of capacitors C arranged in an array along the x direction and the y direction, a first electrode plate of each of the plurality of capacitors C may be commonly connected to a common terminal 3111, and a second electrode plate of each of the plurality of capacitors C may be connected to a corresponding transistor T. For the first dielectric layer 3102, reference may be made to the first dielectric layer 102 in the above examples.

The second dielectric layer 3103 is located on a side of the first dielectric layer 3102 away from the substrate 3101, a transistor array is disposed in the second dielectric layer 3103, the transistor array may comprise a plurality of transistors T arranged in an array along the x direction and the y direction, one transistor T may be connected to the second electrode plate of one corresponding capacitor C, the plurality of capacitors C and the plurality of transistors T may constitute a plurality of memory cells arranged in an array, and the plurality of memory cells constitute a memory cell array. For the second dielectric layer 3103, reference may be made to the second dielectric layer 103 in the above examples.

The plurality of bit lines 3104 are located on a side of the memory cell array, for example, the plurality of bit lines 3104 are located on a side of the second dielectric layer 3103 away from the first dielectric layer 3102. The plurality of bit lines 3104 are arranged along the x direction, each bit line 3104 extends along the y direction, and the plurality of memory cells arranged along the y direction are connected to the same bit line 3104. For bit line 3104, reference may be made to the bit line 104 in the above examples.

A conductive structure (not shown in the figure) is located on the side of the second dielectric layer 3103 away from the first dielectric layer 3102, that is, the conductive structure and the bit line 3104 are located on the same side of the transistor, and the conductive structure and the bit line 3104 are isolated from each other. The conductive structure extends along a first direction and covers at least a portion of the bit line 3104. For the conductive structure, reference may be made to the conductive structure 107 in the above examples.

The first interconnection layer 3120 is located on a side of the bit line 3104 away from the second dielectric layer 3103, and the first interconnection layer 3120 comprises a first interconnection dielectric layer and a plurality of first interconnection structures located in the first interconnection dielectric layer. Each first interconnect structure may comprise a contact structure and a conductive layer. A material of the first interconnection dielectric layer comprises a dielectric material, for example, at least one of silicon oxide, silicon nitride, and silicon oxynitride. A material of the first interconnect structure comprises a conductive material, for example, at least one of polysilicon, doped polysilicon, metal (e.g., tungsten, titanium, tantalum, etc.), metal silicide (e.g., tungsten silicide, titanium silicide, etc.), metal nitride (e.g., tungsten nitride, tantalum nitride, etc.).

For example, a first contact structure 3121 is connected to the bit line 3104, a second contact structure (not shown in the figure) is connected to the conductive structure, a third contact structure 3122 is connected to a word line (as shown by the dotted line in FIG. 16), and a fourth contact structure 3123 is connected to the common terminal 3111. The first contact structure 3121, the second contact structure, the third contact structure 3122, and the fourth contact structure 3123 respectively lead out the bit line 3104, the conductive structure, the word line, and the common terminal 3111. For the first contact structure 3121 and the second contact structure, reference may be made to the first contact structure 109 and the second contact structure 110 in the above examples, respectively.

The first bonding layer 3130 is located on a side of the first interconnection layer 3120 away from the bit line 3104, and the first bonding layer 3130 comprises a first bonding dielectric layer and a plurality of first bonding contacts 3131 located in the first bonding dielectric layer. A material of the first bonding dielectric layer comprises a dielectric material, for example, at least one of silicon oxide, silicon nitride, and silicon oxynitride. A material of the first bonding contact 3131 comprises a conductive material, for example, at least one of copper, gold, and silver.

The second semiconductor structure 3200 comprises a peripheral circuit, a second interconnect layer 3220, and a second bonding layer 3230. The second semiconductor structure 3200 and the first semiconductor structure 3100 may be bonded to each other by the first bonding layer 3130 and the second bonding layer 3230. For the peripheral circuit, reference may be made to the related description of FIG. 1.

The second interconnection layer 3220 is located between the peripheral circuit and the second bonding layer 3230, and the second interconnection layer 3220 comprises a second interconnection dielectric layer and a plurality of second interconnection structures 3221 located in the second interconnection dielectric layer. Each second interconnect structure 3221 may comprise a contact structure and a conductive layer. A material of the second interconnection dielectric layer comprises a dielectric material, for example, at least one of silicon oxide, silicon nitride, and silicon oxynitride. A material of the second interconnect structure 3221 comprises a conductive material, for example, at least one of polysilicon, doped polysilicon, metal (e.g., tungsten, titanium, tantalum, etc.), metal silicide (e.g., tungsten silicide, titanium silicide, etc.), metal nitride (e.g., tungsten nitride, tantalum nitride, etc.).

The second bonding layer 3230 is located on a side of the second interconnection layer 3220 away from the peripheral circuit, and the second bonding layer 3230 comprises a second bonding dielectric layer and a plurality of second bonding contacts 3231 located in the second bonding dielectric layer. A material of the second bonding dielectric layer comprises a dielectric material, for example, at least one of silicon oxide, silicon nitride, and silicon oxynitride. A material of the second bonding contact 3231 comprises a conductive material, for example, at least one of copper, gold, and silver.

It can be understood that the peripheral circuit may be connected to the bit line 3104, the conductive structure, the word line, and the common terminal 3111 through the second interconnection structure 3221, the second bonding contact 3231, the first bonding contact 3131, and the first interconnection structure, respectively, so as to apply electric signal to the bit line 3104, the conductive structure, the word line, and the common terminal 3111 to control the memory cell array to complete a corresponding operation.

In some examples, the first semiconductor structure comprises a plurality of conductive structures arranged along a second direction intersecting with the first direction.

In some examples, the conductive structure has a first conductive portion protruding toward the bit line, and the first conductive portion extends until it is between adjacent bit lines.

In some examples, the first conductive portions of the plurality of conductive structures extend along the second direction and are connected to each other.

In some examples, a height of the first conductive portion is greater than a height of the bit line.

In some examples, the first semiconductor structure further comprises a first contact structure and a second contact structure, the first contact structure is located on a side of the bit line away from the memory cell array and is connected to the bit line, wherein the first contact structure is located between adjacent conductive structures, the second contact structure is located on a side of the conductive structure away from the bit line and is connected to the conductive structure, wherein the second contact structure and the first contact structure are spaced apart.

In some examples, the plurality of second contact structures are respectively connected to the plurality of conductive structures, wherein the plurality of second contact structures are connected to each other.

In some examples, a size of the conductive structure in the second direction is greater than a distance between the adjacent conductive structures.

In some examples, a ratio of the size of the conductive structure in the second direction to the distance between the adjacent conductive structures is greater than 5:1.

In some examples, the first semiconductor structure further comprises a first contact structure located on a side of the bit line away from the memory cell array and connected to an end of the bit line.

In some examples, a distance between the conductive structure and the bit line is greater than 0.

In some examples, the distance between the conductive structure and the bit line is greater than a pitch between the adjacent bit lines.

In some examples, a gap exists between the conductive structure and the bit line.

In some examples, the gap is an air gap.

In some examples, the peripheral circuit is further connected to the conductive structure and configured to provide a fixed potential to the conductive structure.

In some examples, the second semiconductor structure and the first semiconductor structure are respectively located on different regions of a substrate, or the second semiconductor structure is located between the substrate and the first semiconductor structure, or the second semiconductor structure and the first semiconductor structure are bonded to each other.

In examples of the present disclosure, the memory devices may have different architectural configurations. In an example, the second semiconductor structure and the first semiconductor structure are respectively located on different regions of the substrate, and the memory device is a Periphery Near Cell (PNC) architecture. In another example, the second semiconductor structure is located between the substrate and the first semiconductor structure, and the memory device is a Periphery Under Cell (PUC) architecture. In yet another example, the second semiconductor structure and the first semiconductor structure are bonded to each other, as shown in FIG. 16, the memory device is an Xtacking architecture.

The features disclosed in several apparatus examples provided by the present disclosure may be arbitrarily combined without conflict to obtain a new apparatus example.

The methods disclosed in several method examples provided by the present disclosure may be arbitrarily combined without conflict to obtain a new method example.

It should be understood that “one example” or “an example” mentioned throughout the specification means that specific features, structures, or characteristics related to the example are included in at least one example of the present disclosure. Thus, “in one example” or “in an example” appearing throughout the specification does not necessarily refer to the same example. Further, these specific features, structures, or characteristics may be combined in one or more examples in any suitable manner. It should be understood that, in various examples of the present disclosure, the sequence numbers of the above processes do not mean a order of execution sequences, and an execution sequence of each process should be determined by function and intrinsic logic thereof, and should not constitute any limitation on implementation processes of examples of the present disclosure. The sequence numbers of the above examples of the present disclosure are merely for description, and do not represent the advantages or disadvantages of examples.

It should be noted that, in this specification, the terms “comprising”, “including”, or any other variant thereof are intended to cover a non-exclusive inclusion, such that a process, method, article, or apparatus that comprises a series of elements comprises not only those elements but also other elements not explicitly listed, or elements inherent to such a process, method, article, or apparatus. Without further restriction, the element defined by the statement “comprise one . . . ” does not preclude the presence of additional identical elements in the process, method, article, or apparatus that comprises the element.

The above description is only an implementation of the present disclosure, but the protection scope of the present disclosure is not limited thereto, and changes or replacements that can be easily conceived by any person skilled in the art within the technical scope of the present disclosure should be covered within the protection scope of the present disclosure.

What is claimed is:

1. A semiconductor device, comprising:
a plurality of bit lines located on a first side of a transistor and arranged along a first direction; and
a conductive structure located on a second side of the transistor and comprising a first conductive portion and a second conductive portion, the first conductive portion being located between adjacent bit lines of the plurality of bit lines, the second conductive portion being located on a side of the plurality of bit lines away from the transistor, wherein the second conductive portion extends along the first direction and is connected to the first conductive portion between the adjacent bit lines.

2. The semiconductor device of claim 1, wherein the semiconductor device comprises a plurality of conductive structures including the conductive structure, and the plurality of conductive structures are arranged along a second direction intersecting with the first direction, and
wherein first conductive portions of the plurality of conductive structures extend along the second direction and are connected to each other.

3. The semiconductor device of claim 2, further comprising:
a first contact structure located on a side of a bit line away from the transistor and connected to the bit line, wherein the first contact structure is located between adjacent conductive structures of the plurality of conductive structures; and
a second contact structure located on a side of the conductive structure away from the bit line and connected to the conductive structure, wherein the second contact structure and the first contact structure are spaced apart.

4. The semiconductor device of claim 3, wherein the semiconductor device comprises a plurality of second contact structures including the second contact structure, and
wherein the plurality of second contact structures are respectively connected to the plurality of conductive structures, and wherein the plurality of second contact structures are connected to each other.

5. The semiconductor device of claim 2, wherein a size of the conductive structure in the second direction is greater than a distance between adjacent conductive structures in the second direction.

6. The semiconductor device of claim 1, wherein a distance between the second conductive portion and a bit line is greater than 0.

7. The semiconductor device of claim 1, wherein a gap exists between the conductive structure and a bit line, and wherein the gap is an air gap.

8. A memory device, comprising:
a first semiconductor structure comprising a memory cell array, a plurality of bit lines and a conductive structure, the plurality of bit lines being located on a side of the memory cell array and arranged along a first direction, the conductive structure extending along the first direction and covering at least a portion of a bit line of the plurality of bit lines; and
a second semiconductor structure comprising a peripheral circuit connected to the memory cell array through the plurality of bit lines.

9. The memory device of claim 8, wherein the conductive structure comprises a plurality of conductive structures including the conductive structure, and the plurality of conductive structures are arranged along a second direction intersecting with the first direction.

10. The memory device of claim 9, wherein the conductive structure has a first conductive portion protruding toward the bit line, and the first conductive portion extends until the first conductive portion is between adjacent bit lines of the plurality of bit lines, and
wherein first conductive portions of the plurality of conductive structures extend along the second direction and are connected to each other.

11. The memory device of claim 9, wherein the first semiconductor structure further comprises:
a first contact structure located on a side of the bit line away from the memory cell array and connected to the bit line, wherein the first contact structure is located between adjacent conductive structures of the plurality of conductive structures; and
a second contact structure located on a side of the conductive structure away from the bit line and connected to the conductive structure, wherein the second contact structure and the first contact structure are spaced apart.

12. The memory device of claim 11, wherein the second contact structure comprises a plurality of second contact structures including the second contact structure, and the plurality of second contact structures are respectively connected to the plurality of conductive structures, wherein the plurality of second contact structures are connected to each other.

13. The memory device of claim 9, wherein a size of the conductive structure in the second direction is greater than a distance between adjacent conductive structures of the plurality of conductive structures.

14. The memory device of claim 8, wherein a distance between the conductive structure and the bit line is greater than 0.

15. The memory device of claim 8, wherein a gap exists between the conductive structure and the bit line, and
wherein the gap is an air gap.

16. A manufacturing method of a semiconductor device, comprising:
forming a plurality of bit lines arranged along a first direction on a first side of a transistor; and
forming a conductive structure on a second side of the transistor, wherein the conductive structure comprises a first conductive portion and a second conductive portion, the first conductive portion is located between adjacent bit lines of the plurality of bit lines, the second conductive portion is located on a side of the plurality of bit lines away from the transistor, and the second conductive portion extends along the first direction and is connected to the first conductive portion between the adjacent bit lines.

17. The manufacturing method of claim 16, wherein forming the conductive structure on the second side of the transistor comprises:
forming a spacer layer covering sidewalls of each of the plurality of bit lines and a surface of each of the plurality of bit lines away from the transistor;
forming an initial conductive structure covering the transistor and the spacer layer, wherein the initial conductive structure comprises an initial first conductive portion and an initial second conductive portion, the initial first conductive portion is located between adjacent spacer layers and extends along a second direction, the initial second conductive portion extends along the first direction and is connected to the initial first conductive portion between the adjacent spacer layers, and the second direction intersects with the first direction; and
etching the initial conductive structure to form a plurality of first trenches arranged along the second direction, wherein a first trench exposes the spacer layer of the sidewalls of each of the plurality of bit lines and the surface of each of the plurality of bit lines away from the transistor, the initial first conductive portion between adjacent first trenches of the plurality of first trenches constitutes the first conductive portion, and the initial second conductive portion between the adjacent first trenches constitutes the second conductive portion.

18. The manufacturing method of claim 17, further comprising:
removing the exposed spacer layer to form a gap between the bit line and the conductive structure.

19. The manufacturing method of claim 18, further comprising:
forming a dielectric layer filling the first trench and covering the second conductive portion;
forming a first contact structure extending to the bit line in the dielectric layer, wherein the first contact structure is located between adjacent conductive structures; and
forming a second contact structure extending to the conductive structure in the dielectric layer, wherein the second contact structure and the first contact structure are spaced apart.

20. The manufacturing method of claim 16, wherein forming the conductive structure on the side of the transistor comprises:
forming a spacer layer covering sidewalls of each of the plurality of bit lines and a surface of each of the plurality of bit lines away from the transistor;
forming the first conductive portion between adjacent spacer layers, wherein the first conductive portion extends along a second direction intersecting with the first direction;
removing the spacer layer to form a gap between each of the plurality of bit lines and the first conductive portion;
forming a dielectric layer covering the first conductive portion, the gap, and the plurality of bit lines, wherein the dielectric layer has a protrusion toward the bit line;
etching the dielectric layer to form a plurality of second trenches arranged along the second direction, wherein a bottom of the second trench exposes the first conductive portion; and
forming the second conductive portion in the second trench.
